(19) United States
(12) Patent Application Publication
(10) Pub. No.: US 2012/0019496 A1
(43) Pub. Date: Jan. 26, 2012

(54) OPTICAL SENSOR CIRCUIT, DISPLAY DEVICE AND METHOD FOR DRIVING OPTICAL SENSOR CIRCUIT

(75) Inventors: Atsuhito Murai, Osaka-shi (JP); Yoshiharu Kataoka, Osaka-shi (JP); Takuya Watanabe, Osaka-shi (JP); Hajime Imai, Osaka-shi (JP); Hideki Kitagawa, Osaka-shi (JP)

(73) Assignee: Sharp Kabushiki Kaisha, Osaka-shi (JP)

(21) Appl. No.: 13/258,775

(22) PCT Filed: Oct. 27, 2009
(86) PCT No.: PCT/JP2009/068419

§ 371 Date: Sep. 22, 2011

(30) Foreign Application Priority Data
Mar. 30, 2009 (JP) 2009-083451

(51) Int. Cl. G09G 5/00; H01L 31/0368; H01L 29/786; H01L 31/0376

(52) U.S. Cl. 345/207; 257/60; 257/71; 257/E31.043; 257/E31.047; 257/E29.273

(57) ABSTRACT

A field-effect transistor (62a) has a back gate (62ag2). The back gate (62ag2), a cathode of a photodiode (62b), and a first end of a first capacitor (62c) are connected with each other via a first node (netA). An anode of the photodiode (62b) is connected with a first line (Vrst). A second end of the first capacitor (62c) is connected with a second line (Csn). A gate (62ag1) of the field-effect transistor (62a) is connected with a third line (Vrwn), and a drain of the filed-effect transistor (62a) is connected with a fourth line (Vsm). A source of the field-effect transistor (62a) is an output of an output amplifier (62a).

### TECHNICAL FIELD

The present invention relates to an optical sensor circuit and a display device including the optical sensor circuit.

### BACKGROUND ART

There have been known liquid crystal display devices having optical sensors in picture elements or pixels (see Patent Literature 1 for example). A configuration of such a liquid crystal display device is described with reference to FIG. 14.

FIG. 14 shows a configuration of an n^{th} horizontal row in a display region of a liquid crystal display panel. The configuration of the n^{th} horizontal row includes (i) a plurality of picture elements PIX defined by a gate line Gn, source lines S (in the figure, Sm to Sm+3 are shown), and a retention capacitor line Csn, and (ii) one or more optical sensor circuits 102 connected with a reset line Vrstn and a readout control line Vrwn. “n” and “m” at the end of a sign indicate a horizontal row number and a longitudinal column number, respectively.

Each of the picture elements PIX includes a TFT 101a serving as a selection element, a liquid crystal capacitor CL, and a retention capacitor CS. A gate of the TFT 101a is connected with the gate line Gn, a source of the TFT 101a is connected with the source line S, and a drain of the TFT 101a is connected with a picture element electrode 103. The liquid crystal capacitor CL is a capacitor formed by providing a liquid crystal layer between the picture element electrode 103 and a common electrode Com. The retention capacitor CS is a capacitor formed by providing an insulating film between the picture element electrode 103 or a drain electrode of the TFT 101a and the retention capacitor line Csn. Constant voltages, for example, are applied to the common electrode Com and the retention capacitor line Csn.

The optical sensor circuit 102 is provided in any number. For example, one optical sensor circuit 102 may be provided for each picture element PIX or each pixel (e.g. a set of picture elements PIX corresponding to R, G, and B). The optical sensor circuit 102 includes a TFT 102a, a photodiode 102b, and a capacitor 102c. A gate of the TFT 102a is connected with an electrode called a node netA, a drain of the TFT 102a is connected with one source line S (here, Sm), and a source of the TFT 102a is connected with another one source line S (here, Sm+1). An anode of the photodiode 102b is connected with the reset line Vrstn and a cathode of the photodiode 102b is connected with the node netA. A first end of the capacitor 102c is connected with the node netA and a second end of the capacitor 102c is connected with the readout control line Vrwn.

A voltage having a level being dependent on intensity of light incident on the photodiode 102b appears on the node netA. Within a period other than a writing period during which a data signal is written into the picture element PIX, the optical sensor circuit 102 outputs this voltage as a sensor output voltage Vom via the source of the TFT 102a so that the sensor output voltage Vom is supplied to a sensor readout circuit outside the display region via the source line S connected with the source of the TFT 102a (this source line S serves as a sensor output line Vom when light is detected (for convenience of explanation, the sensor output line and the sensor output voltage are given the same reference signs)). At that time, the TFT 102a serves as a source follower. Further, when the light is detected, the source line S connected with the drain of the TFT 102a serves as a power source line Vsm to which a constant voltage is applied. Alternatively, the sensor output line Vom and the power source line Vsm may be provided independently of the source lines S, as shown by dashed lines close to the source lines S.

With reference to FIG. 15, the following describes in detail how the optical sensor circuit 102 operates at the time above.

During a writing period during which data signals are written, a gate pulse is outputted as a scanning signal to the gate line Gn, and the data signals are outputted to the source lines S. For example, the gate pulse consists of +24 High level and −16V low level. A constant voltage (e.g. +4V) is applied to the retention capacitor line Csn. This operation is repeated with respect to picture elements PIX in each horizontal row every one vertical period (1V). Within a period other than the writing period, a result of light detection by the optical sensor circuit 102 can be outputted to the sensor readout circuit.

At a time (1), when a reset pulse Prstn consisting of −4V High level and −16V Low level, for example, is applied from an outside sensor drive circuit to the reset line Vrstn, the photodiode 102b is conductive in a forward direction, and a voltage at the node netA is reset to the voltage supplied via the reset line Vrstn. Thereafter, during a period (2), a leakage occurs in the photodiode 102b that is now in a reverse biased state. A level of the leakage is dependent on the intensity of the light irradiation to the photodiode 102b. Thus, the voltage at the node netA drops at a rate corresponding to the light intensity.

At a time (3), when a readout pulse Prwn consisting of +24V High level and −10V Low level, for example, is applied from the sensor drive circuit to the readout control line Vrwn, the voltage at the node netA increases. It is arranged so that the voltage at the node netA increases beyond a threshold voltage of the TFT 102a. The sensor output voltage Vom outputted from the source of the TFT 102a while the readout pulse Prwn is applied corresponds to the voltage at the node netA, i.e. the light intensity. Accordingly, by the sensor readout circuit reading the sensor output voltage Vom via the sensor output line Vom, it is possible to detect the light intensity. The optical sensor circuit 102 ends the output at a time (4), and stops its operation until next reset operation.

### CITATION LIST

### Patent Literature 1

International Publication No. 2007/145347 (Publication Date: Dec. 21, 2007)

### Patent Literature 2

U.S. Pat. No. 6,995,743 (Publication Date: Feb. 7, 2006)

### SUMMARY OF INVENTION

### Technical Problem

However, in a liquid crystal display device including the conventional optical sensor circuit, a voltage VnetA at a node netA corresponds to an intensity of light irradiation on a photodiode 102b. As such, respective photodiodes 102b have different irradiation histories by having been irradiated differently from each other, so that each of gates of TFTs 102a of sensor circuits 102 which gates are connected with nodes netA has a different voltage application history. Accordingly, different direct voltage components are applied to the gates of the respective TFT 102a which are output amplifiers. Thus, there are differences in size of shift phenomena of threshold voltages of the TFTs 102a. Consequently, there are variations in sensor output voltages Vo from the respective sensor circuits 102. This causes a deterioration in light detection accuracy of the liquid crystal display device.

Patent Literature 2 discloses an optical sensor circuit as shown in FIG. 16. A photodiode shown in FIG. 16 is a Photo TFT formed by a TFT whose gate and drain are connected with each other (a so-called diode-connected TFT). An output of the Photo TFT is connected with a drain of a Readout TFT which is a TFT for performing readout. When the Readout TFT is in an ON state, a sensor output is outputted by a source of the Readout TFT and read out by a charge readout amplifier.

According to a configuration shown in FIG. 16, no output of the Photo TFT (i.e., a photodiode) is connected with a gate of the TFT. However, an output of the photodiode is directly outputted, via the drain through the source of the Readout TFT, to an input of the charge readout amplifier (load) and a line connected with the input of the charge readout amplifier. Thus, the output of the photodiode is outputted without being amplified by the Readout TFT. Accordingly, it is necessary that a capacitor Cst2 connected with the output of the Photo TFT have a great capacitance value and that the Readout TFT is turned into an ON state after the capacitor Cst2 is charged with the output of the Photo TFT for an extended period of time. This requires an increase in device size of the capacitor Cst2. However, with this requirement, a reverse bias voltage applied to the photodiode must be increased, so that a great current capacity of the photodiode can be obtained. In such circumstance, the photodiode is increased in size so as to have great resistance to pressure and a low resistivity. This causes a decrease in an aperture ratio of a display device.

As described above, the conventional display device including the optical sensor circuit provided in a display region has a problem that it is difficult that shift phenomena of threshold voltages of TFT, which serve as output amplifiers for efficiently amplifying week outputs of photodiodes, are uniform with each other.

The present invention is made in view of the problem, and an object of the present invention is to realize (i) an optical sensor circuit in which it is possible that shift phenomena of threshold voltages of TFTs, which serve as output amplifier for efficiently amplifying week outputs of photodiodes, are uniform with each other, (ii) a display device including the optical sensor circuit, and (iii) a method for driving the optical sensor circuit.

### Solution to Problem

In order to attain the object, an optical sensor circuit of the present invention at least includes: a photodiode; and a common-drain field-effect transistor whose threshold voltage changes depending on an intensity of light irradiation to the photodiode.

The invention is different from a conventional technique that produces a difference in an optical sensor output for an intensity of light irradiation on a photodiode by directly changing a given electrode potential of the field-effect transistor, which serves as an optical sensor output device. The invention is a technique capable of producing a difference in an optical sensor output indirectly by not directly changing any electrode potential of the field-effect transistor but changing the threshold voltage of the common-drain field-effect transistor (i.e., the field-effect transistor capable of outputting an amplified output from the source). Consequently, it is possible to simply the method for driving the optical sensor circuit and to reduce a shift in the threshold voltage of the filed-effect transistor.

In order to attain the object, a display device of the present invention includes the optical sensor circuit.

According to the invention, the optical sensor circuit is provided in the display device. As such, even in a case where the first capacitor or the photodiode is smaller in device size than a capacitor or a photodiode in a conventional optical sensor circuit, it is still possible to obtain an optical sensor output difference similar to that of the conventional optical sensor circuit. This can bring about an effect that a decrease in an aperture ratio can be prevented.

In order to attain the object, a method of the present invention for driving an optical sensor circuit including a first circuit, the first circuit including a photodiode, a first capacitor, and an output amplifier which are provided in a display region, the output amplifier being a field-effect transistor, the field-effect transistor having a back gate, a cathode of the photodiode, a first end of the first capacitor, and the back gate being connected with each other via a first node, an anode of the photodiode being connected with a first line via which a voltage is applied to the anode of the photodiode, a second end of the first capacitor being connected with a second line via which a voltage is applied to the second end of the first capacitor, a gate of the field-effect transistor being connected with a third line via which a voltage is applied to the gate of the field-effect transistor, a drain of the field-effect transistor being connected with a fourth line via which a voltage is applied to the drain of the filed-effect transistor, and a source of the filed-effect transistor being an output of the output amplifier, the method including the steps of: applying a first predetermined direct voltage to the second line and a second predetermined direct voltage to the fourth line; applying, to the first line, a first pulse for causing the photodiode to be conductive in a forward direction; applying a reverse bias voltage to the photodiode when a period during which the first pulse is applied is ended; applying a second pulse to the third line when a predetermined time is passed after the end of the period, so as to change an OFF state of the field-effect transistor to an ON state; and obtaining an output voltage from the output of the output amplifier in a period during which the second pulse is applied to the third line.

According to the invention, when the period during which the first pulse is applied to the photodiode is ended, the photodiode is in such a state that the reverse bias voltage is applied to the photodiode. As such, within the predetermined period, a leak current having a level being dependent on the intensity of the light irradiation on the photodiode occurs in the photodiode so that the voltage at the first node corresponds to the intensity of the light irradiation. Then, after the predetermined period, the second pulse is applied to the third line so as to change the OFF state of the field-effect transistor to the ON state. In this case, since the back gate voltage corresponds to the intensity of the light irradiation, the output voltage of the output amplifier corresponds to the intensity of the light irradiation.

With this, it is possible to obtain, from the output amplifier, a suitable output voltage corresponding to the intensity of the light irradiation.

This can bring about an effect that the method for driving the optical sensor circuit can be realized, whereby shift phenomena of threshold voltage of TFTs, which TFTs serve as output amplifiers for efficiently increasing week outputs of photodiodes, are uniform with each other.

### Advantageous Effects of Invention

As described early, the optical sensor circuit of the present invention at least includes: a photodiode and a common-drain field-effect transistor whose threshold voltage changes depending on an intensity of light irradiation on the photodiode. Accordingly, the invention is a technique capable of producing a difference in an optical sensor output indirectly by changing a threshold voltage of a common-drain field-effect transistor (i.e., a field-effect transistor capable of outputting an amplified output from a source), unlike a conventional art that produces a difference in an optical sensor output for an intensity of light irradiation on the photodiode by directly changing a given electrode potential of the common-drain field-effect transistor, which serves as an optical sensor output device. More specifically, the optical sensor circuit of the present invention includes a first circuit including the photodiode, a first capacitor, and an output amplifier which is a common-drain field-effect transistor, the common-drain field-effect transistor having a back gate, a cathode of the photodiode, a first end of the first capacitor, and the back gate of the common-drain field-effect transistor being connected with each other via a first node, an anode of the photodiode being connected with a first line via which a voltage is applied to the anode of the photodiode, a second end of the first capacitor being connected with a second line via which a voltage is applied to the second end of the first capacitor, a gate of the common-drain field-effect transistor being connected with a third line via which a voltage is applied to the gate of the common-drain field-effect transistor, a drain of the common-drain field-effect transistor being connected with a fourth line via which a voltage is applied to the drain of the common-drain field-effect transistor, and a source of the common-drain field-effect transistor being an output of the output amplifier.

As described early, a method of the present invention for driving an optical sensor circuit including a first circuit, the first circuit including a photodiode, a first capacitor, and an output amplifier which are provided in a display region, the output amplifier being a field-effect transistor, the field-effect transistor having a back gate, a cathode of the photodiode, a first end of the first capacitor, and the back gate being connected with each other via a first node, an anode of the photodiode being connected with a first line via which a voltage is applied to the anode of the photodiode, a second end of the first capacitor being connected with a second line via which a voltage is applied to the second end of the first capacitor, a gate of the field-effect transistor being connected with a third line via which a voltage is applied to the gate of the field-effect transistor, a drain of the field-effect transistor being connected with a fourth line via which a voltage is applied to the drain of the filed-effect transistor, and a source of the filed-effect transistor being an output of the output amplifier, the method including the steps of: applying a first predetermined direct voltage to the second line and a second predetermined direct voltage to the fourth line; applying, to the first line, a first pulse for causing the photodiode to be conductive in a forward direction; applying a reverse bias voltage to the photodiode when a period during which the first pulse is applied is ended; applying a second pulse to the third line when a predetermined time is passed after the end of the period, so as to change an OFF state of the field-effect transistor to an ON state; and obtaining an output voltage from the output of the output amplifier in a period during which the second pulse is applied to the third line.

With the above, it is possible to bring about an effect that can realize an optical sensor circuit in which the TFTs, which serve as output amplifiers for efficiently increasing weak outputs of photodiodes, are such that their shift phenomena of threshold voltages are uniform with each other.

### BRIEF DESCRIPTION OF DRAWINGS

FIG. 1 is a circuit view showing a configuration of a display region including an optical sensor circuit, according to an embodiment of the present invention.

FIG. 2 is a waveform chart for explaining an operation of the optical sensor circuit shown in FIG. 1.

FIG. 3 is a graph showing curved lines representing characteristics of a field-effect transistor used in an output amplifier shown in FIG. 1.

FIG. 4 is a graph for explaining detection performances of a conventional optical sensor circuit which is compared with the optical sensor circuit shown in FIG. 1.

FIG. 5 is a graph for explaining detection performances of the optical sensor circuit shown in FIG. 1.

FIG. 6 is a block view showing a configuration of a display device having the display region shown in FIG. 1.

FIG. 7 is a plan view showing an example of pattern positioning in the display region according to the embodiment of the present invention.

FIG. 8 is a cross sectional view taken along the line A-A′ of FIG. 7.

FIG. 9 is a cross sectional view taken along the line B-B′ of FIG. 7.

FIG. 10 is a plan view showing an example of pattern positioning in a conventional display region compared with the embodiment of the present invention.

FIG. 11 is a cross sectional view taken along the line A-A′ of FIG. 10.

FIG. 12 is a cross sectional view taken along the line B-B′ of FIG. 10.

FIG. 13 is a cross sectional view taken along the line C-C′ of FIG. 10.

FIG. 14 is a circuit view showing a first configuration in a display region according to a conventional art.

FIG. 15 is a waveform chart for explaining how the first configuration of the display region shown in FIG. 14 operates.

FIG. 16 is a circuit view showing a second configuration in the display region according to a conventional art.

FIG. 17 is a circuit view showing a third configuration in the display region according to a conventional art, the third configuration of the display region being equivalent to the second configuration of the display region shown in FIG. 16.

### DESCRIPTION OF EMBODIMENTS

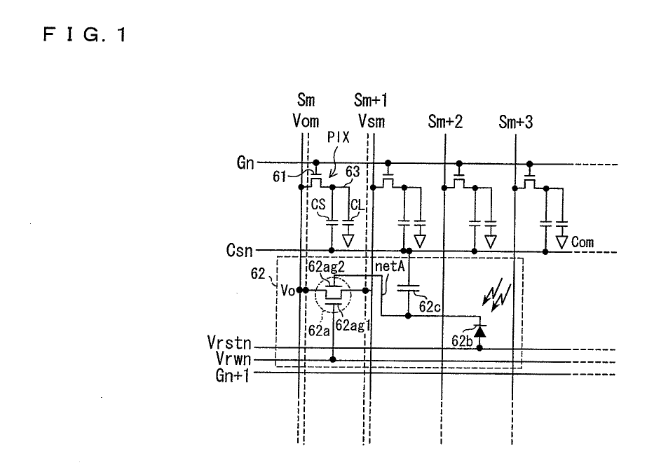

An embodiment of the present invention is described below with reference to FIGS. 1 through 13 and 17. The embodiment deals with an exemplary case in which an optical sensor circuit of the present invention is applied in a liquid crystal display device.

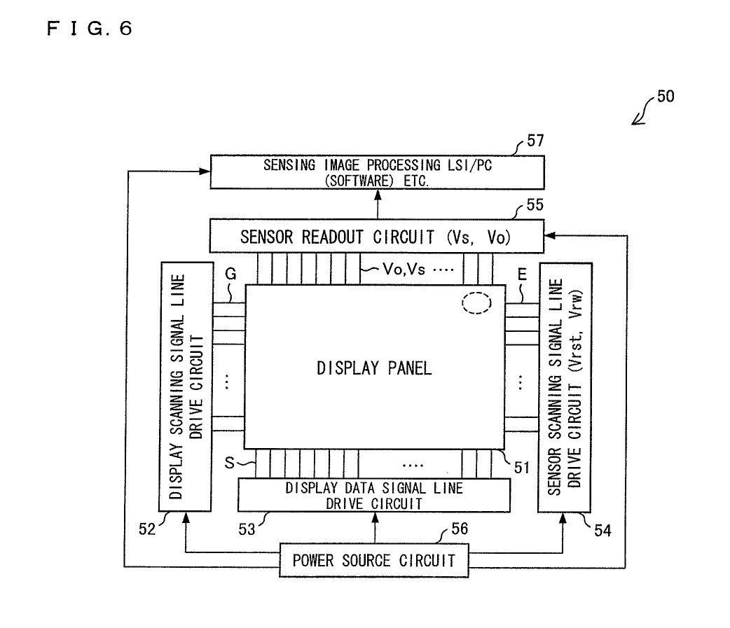

FIG. 6 shows a configuration of a liquid crystal display device (display device) 50 of the present embodiment.

The liquid crystal display device 50 is an active matrix display device including a display panel 51, a display scanning signal line drive circuit 52, a display data signal line drive circuit 53, a sensor scanning signal line drive circuit 54, a sensor readout circuit 55, a power source circuit 56, and a sensing image processor 57.

The display panel 51 includes a plurality of gate lines G and a plurality of source lines S crossing the plurality of gate lines G. The display panel 51 has a display region where picture elements PIX, which are provided for respective intersections of the plurality of gate liens G and the plurality of source lines S, are provided in a matrix manner.

The display scanning signal line drive circuit 52 drives the plurality of gate lines G by sequentially outputting, to them, scanning signals for selecting picture elements PIX into which data signals are to be written. The display data signal line drive circuit 53 drives the plurality of source lines S by outputting data signals to them. The sensor scanning signal line drive circuit (which is a drive circuit of a first circuit) 54 line-sequentially drives sensor scanning signal lines E by sequentially outputting, to them, scanning signals (voltage Vrst, voltage Vrw) for causing a sensor circuit to operate. The sensor readout circuit 55 reads sensor output voltages Vo from sensor output lines Vo (for convenience of explanation, the sensor output lines and the sensor output voltages are given the same reference signs), and supplies power source voltages to sensor power source lines Vs. The power source circuit 56 supplies power sources required for operations of the display scanning signal line drive circuit 52, the display data signal line drive circuit 53, the sensor scanning signal line drive circuit 54, the sensor readout circuit 55, and the sensing image processor 57. The sensing image processor 57 analyzes distribution of a sensor detection result in a panel plane, based on the sensor output voltages Vo read by the sensor readout circuit 55.

The functions of the sensor scanning signal line drive circuit 54 and the sensor readout circuit 55 may be included in other circuits such as the display scanning signal line drive circuit 52, the display data signal line drive circuit 53, and the like. Further, the function of the sensor readout circuit 55 may be included in the sensing image processor 57. Further, the sensing image processor 57 may be provided in the form of LSI, a computer, or the like in the liquid crystal display device 50. Alternatively, the sensing image processor 57 may be provided outside the liquid crystal display device 50. Similarly, the sensor readout circuit 55 may be provided outside the liquid crystal display device 50.

FIG. 1 shows a configuration of the display region in detail.

FIG. 1 shows a configuration of an n^{th} horizontal row in the display region. The n^{th} horizontal row in the display region includes (i) a plurality of picture elements PIX defined by a gate line Gn, source lines S (which are source lines Sm through Sm+3 in the figure), and a retention capacitor line Csn and (ii) one or more optical sensor circuits 62 connected with a reset line (first line) Vrstn and a readout control line (third line) Vrwn which are sensor scanning signal lines E (see FIG. 6) of two different types. The retention capacitor line (second line) Csn, the reset line Vrstn, and the readout control line Vrwn are provided so as to be extended in parallel with the gate line Gn.

Each of the picture elements PIX includes a TFT 61 serving as a selection element, a liquid crystal capacitor CL, and a retention capacitor CS. A gate of the TFT 61 is connected with the gate line Gn, a source of the TFT 61 is connected with a corresponding one of the source lines S, and a drain of the TFT 61 is connected with a picture element electrode 63. The liquid crystal capacitor CL is a capacitor formed by providing a liquid crystal layer between the picture element electrode 63 and a common electrode Com. The retention capacitor CS is a capacitor formed by providing an insulating film between the picture element electrode 63 or the drain electrode of the TFT 61 and the retention capacitor line Csn. For example, constant voltages are applied to the common electrode Com and the retention capacitor line Csn. The constant voltage applied to the retention capacitor line Csn is a first predetermined direct voltage.

The optical sensor circuit 62 is provided in any number. For example, one optical sensor circuit 62 is provided for each picture element PIX or each pixel (e.g. a set of picture elements PIX corresponding to R, G, B). The optical sensor circuit 62 includes a first circuit including (i) a TFT 62a, (ii) a photodiode (light-receiving element) 62b, and (iii) capacitors 62c and 62d. A gate (input of output amplifier) 62ag1 of the TFT (field-effect transistor, output amplifier) 62a is connected with a readout line (third line) Vrwn, a drain of the TFT 62a is connected with a corresponding one of the source lines (fourth line) S (here, Sm), and a source (output of output amplifier) of the TFT 62a is connected with another of the source lines S (here, Sm+1). The TFT 62a has a back gate 62ag2 connected with an electrode called a node (first node) netA. An anode of the photodiode 62b is connected with the reset line (first line) Vrstn and a cathode of the photodiode 62b is connected with the node netA. A first end of the capacitor (first capacitor) 62c is connected with the node netA and a second end of the capacitor 62c is connected with the retention capacitor line Csn, so that a capacitor is formed between the node netA and the retention capacitor line Csn with a gate insulating film therebetween. A capacitor 62c is provided depending on a size of capacitance required by the node netA. As such, if the size of capacitance required by the node netA is sufficiently met by capacitance of lines including the node netA, it is not necessary to independently form the capacitor 62c. The capacitor 62c is formable by parasitic capacitance between the lines including the node netA and other lines. Hence, even in a case where it is required that the capacitor 62c be independently formed, it is not necessarily required to intentionally build in a capacitor element.

The optical sensor circuit 62 may further include an element other than the above.

Within a period other than a writing period during which data signals are written into picture elements PIX, a voltage having a level being dependent on intensity of light incident on the photodiode 62b appears at the node netA and is outputted as a sensor output voltage Vo from the source of the TFT 62a to the sensor readout circuit outside the display region via the source line S (which serves as a sensor output line Vom when light is detected) connected with the source of the TFT 62a. When the light is detected, the source line S connected with the drain of the TFT 62a serves as a power source line Vsm to which a constant voltage (second predetermined direct voltage) is applied. Alternatively, the sensor output line (sixth line) Vom and the power source line (fifth line) Vsm may be provided independently of the source lines S, as shown by the dashed lines close to the source lines S.

The threshold voltage of the TFT 62a is changed depending on a voltage applied to the back gate 62ag2 of the TFT 62a. Here, the TFT 62a is an n-channel type. The greater the voltage applied to the back gate 62ag2 is, the smaller the threshold voltage of the TFT 62ag2 is, and the smaller the voltage applied to the back gate 62ag2 is, the greater the threshold voltage of the TFT 62a is.

With the threshold voltage of the TFT 62a being decreased, application of a voltage of the readout pulse Prwn to the gate 62ag1 will cause the TFT 62a to output a greater output current. This greater output current is greater than a current outputted from a TFT 62a with no back gate 62ag2, because a voltage between a gate and a source of the TFT 62a has a greater overdrive voltage corresponding to the decreased threshold voltage. On the other hand, with the threshold voltage of the TFT 62a being increased, application of the voltage of the readout pulse Prwn to the gate 62ag1 will cause the TFT 62a to output a greater output current. This greater output current is greater than a current outputted from a TFT 62a with no back gate 62ag2, because the voltage between the gate and the source of the TFT 62a has a smaller overdrive voltage corresponding to the increased threshold voltage. At this time, the TFT 62a should be operated in a saturation region so that the increased output current of the TFT 62a can be constant.

In the present example, it is a design matter what back gate voltage corresponds to a threshold voltage same as one obtained in a case where no back gate 62a is provided. A size of the threshold voltage of the TFT 62ag2 should be determined depending on a size of the back gate voltage applied to the back gate 62ag2. Here, the TFT 62a is not a linear amplifier. However, it is configured so that, as long as the intensity of the light irradiation is in a desired detection range, the TFT 62a is turned into the ON state in response to a whole range of the resultant voltages VnetA when the readout pulse Prwn is applied to the TFT 62a. An output scheme of the TFT 62a is, irrespective of a value of the threshold voltage, such that the source of the TFT 62a outputs an output corresponding to a gate input. In this regard, the TFT 62a is a type of a source follower. That is, the TFT 62a is a common-drain field-effect transistor. In the TFT 62a, it is considered that an input to the TFT 62a is an overdrive voltage which is a voltage between the gate 62ag1 and the source 62 as of the TFT 62a in excess of a threshold voltage of the TFT 62a. Since the threshold voltage of the TFT 62a is changed depending on the intensity of the light irradiation on the photodiode 62b, the overdrive voltage (i.e., the input) is changed. Consequently, an output corresponding to the input thus changed is outputted from the source. The TFT 62a can be further considered as a level shifter of the input.

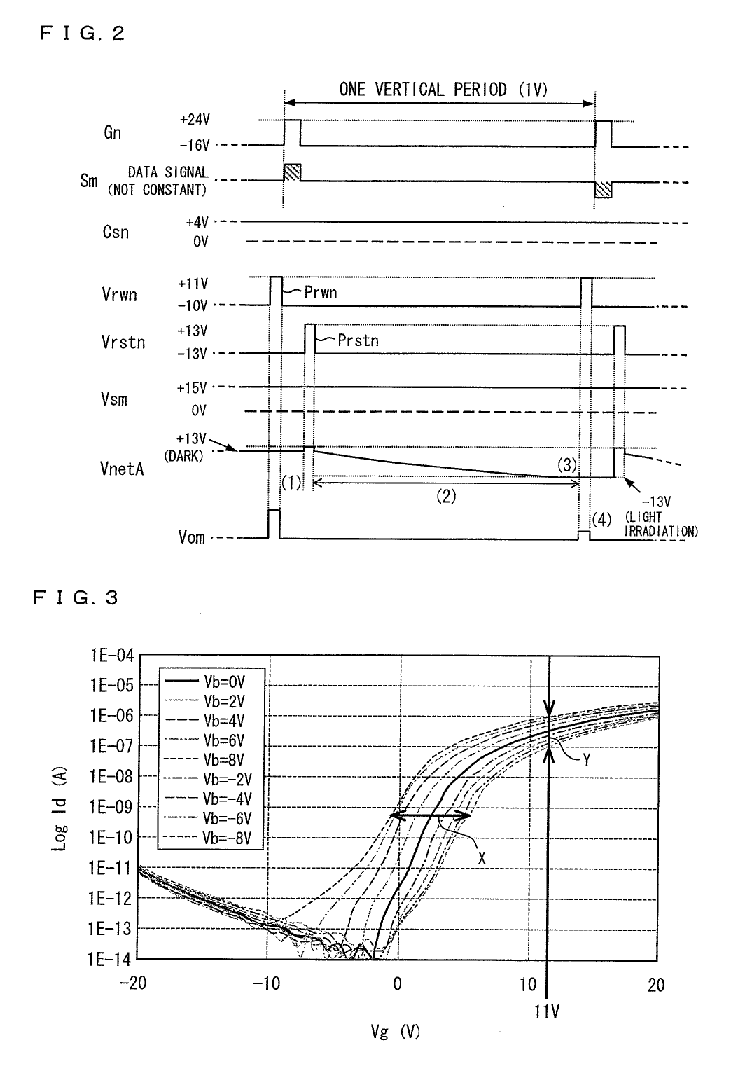

With reference to FIG. 2, the following describes the operation of the optical sensor circuit 62 in detail.

Within a writing period during which data signals are written, a gate pulse (e.g., a gate pulse consisting of +24V High level and −16V Low level) is outputted as a scanning signal to the gate line Gn, and the data signals are outputted to the respective source lines S. A constant voltage (e.g. +4V) is applied to the retention capacitor line Csn. This operation is repeated with respect to picture elements PIX in each horizontal row every one vertical period (1V). Within a period other than the writing period, the result of light detection by the optical sensor circuit 62 can be outputted to the sensor readout circuit 55. In a case where the sensor output line Vom and the power source line Vsm are provided independently of the source lines S, as shown by the dashed lines close to the source lines S, the result of light detection by the optical sensor circuit 62 can be outputted to the sensor readout circuit 55 irrespectively of whether the timing of the output is in the writing period or not.

At a time (1), when a reset pulse Prst consisting of −4V High level and −16V Low level, for example, is applied from an outside sensor drive circuit to the reset line Vrstn, the photodiode 62b is conductive in a forward direction, and a voltage VnetA at the node netA is reset to the voltage supplied via the reset line Vrstn. Thereafter, during a period (2), a leakage having a level being dependent on the intensity of the light incident on the photodiode 62b occurs in a reverse biased state, so that the voltage VnetA at the node net A drops at a rate corresponding to the intensity of the light.

At a time (3), when a readout pulse Prwn consisting of +11V High level and −10V Low level, for example, is applied to the readout control line Vrwn from the sensor scanning signal drive circuit 54, the TFT 62a is turned into an ON state. At the time (3), the greater the intensity of the light incident on the photodiode 62b is, the smaller the voltage VnetA is, and the smaller the intensity of the light incident on the photodiode 62b is, the greater the voltage VnetA is. The voltage VnetA is a back gate voltage of the TFT 62a. FIG. 2 shows an example that the voltage VnetA, i.e., the back gate voltage, is −13V in a case where the intensity of the light incident on the photodiode 62b is the greatest. In a case where absolutely no light is incident on the photodiode 62b, the voltage VnetA is being kept at +13V (which is an initial value within the period (2)) during the time 3.

The light detection voltage outputted from the source of the TFT 62a while the readout pulse Prwn is applied corresponds to the voltage at the node netA, i.e. the intensity of the light irradiation. Hence, by the sensor readout circuit 55 reading out the light detection voltage (source output voltage) via the sensor output line Vom, it is possible to determine the intensity of the light irradiation. The optical sensor circuit 62 ends the sensor output at a time 4, and thereafter stops its operation until next reset operation.

FIG. 3 shows examples of a relationship between (i) a drain current Id of the TFT 62a which drain current Id corresponds to High/Low of the back gate voltage Vb applied to the back gate 62ag2 and (ii) the gate voltage Vg. The vertical axis of the graph in FIG. 3 shows common logarithms of the drain current Id. FIG. 3 shows, with respective curve lines, back gate voltages Vb of every 2V in a range of +8V or greater but +8 or smaller. As shown in the range X, it is demonstrated that the greater the back gate voltages Vb are, the smaller the threshold voltages are so that the TFT 62a is more easily turned into the ON state. In the waveform chart shown in FIG. 2, the voltage of the readout pulse Prwn applied to the gate 62ag1 of the TFT 62a is +11V. As shown in the range Y of FIG. 3, with the gate voltage being same, an ON current of the TFT 62a is greater in a case where the back gate voltage Vb is greater.

Here, the optical sensor circuit 62 of the present embodiment and the optical sensor circuit 102 of the conventional art are compared with each other in terms of their performances of detection of intensity of light irradiation.

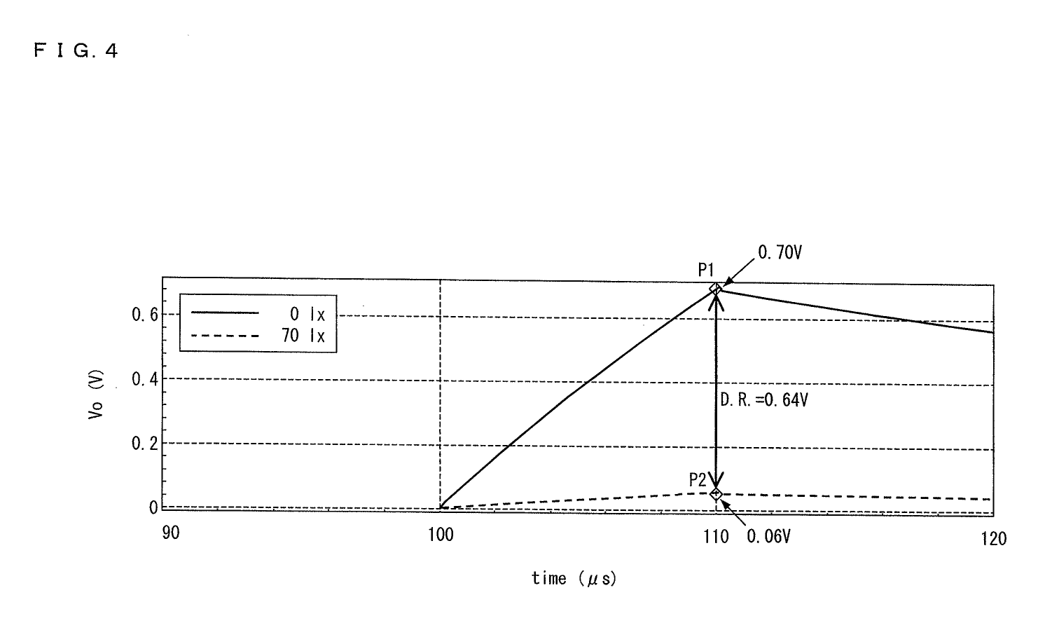

FIG. 4 shows detection performance of the optical sensor circuit 102 of the conventional art. The photodiode 102b is a diode-connected TFT whose L/W (channel length/channel width)=4 μm/50 μm. The capacitance value of the capacitor 102c for boosting a voltage at the node netA is 0.25 pf. The TFT 102a serving as the output amplifier has L/W (channel length/channel width)=4 μm/60 μm.

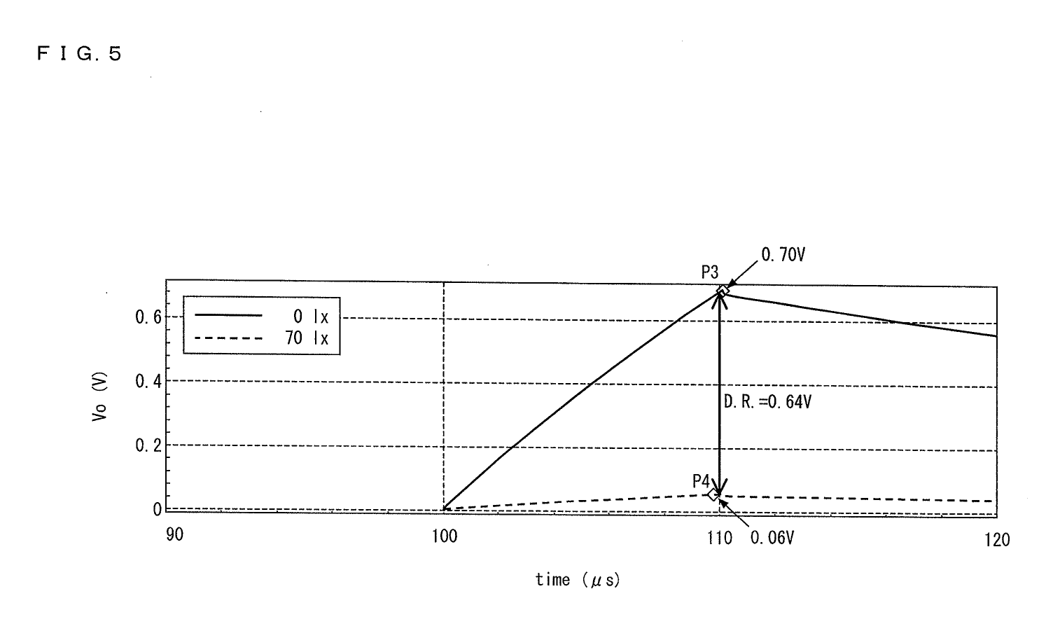

FIG. 5 shows detection performance of the optical sensor circuit 62 of the present embodiment. The photodiode 62b is a diode-connected TFT whose L/W (channel length/channel width)=4 μm/20 μm. The capacitance value of the capacitor 62 for boosting the voltage at the node netA is 0.10 pf. The TFT 62a serving as the output amplifier has L/W (channel length/channel width)=4 μm/60 μm.

Each of FIGS. 4 and 5 shows how greatly sensor output voltages Vo are increased within a period of 10 μs (in each of FIGS. 4 and 5, a period between times 100 μs and 110 μs), one of which sensor output voltages Vo is obtained in a case where the intensity of light irradiation on a photodiode is zero 1× (irradiation with no light) and the other of which sensor output voltages Vo is obtained in a case where the intensity of light irradiation on the photodiode is 70 1× (irradiation with light). In FIG. 4, the sensor output voltage Vo obtained in response to the irradiation with no light is 0.70 V at a point P1 (i.e., the time 110 μs), and the sensor output voltage Vo obtained in response to the irradiation with light is 0.06 V at a point P2 (i.e., the time 110 μs). In FIG. 5, the sensor output voltage Vo obtained in response to the irradiation with no light is 0.70 V at a point 3 (i.e., the time 110 μs), and the sensor output voltage Vo obtained in response to the irradiation with light is 0.06 V at a point 4 (i.e., the time 110 μs). In FIG. 4, a difference between the sensor output voltages at the points 1 and 2 is obtained as an optical sensor output difference corresponding to a voltage difference of D.R.=0.64 V. In FIG. 5, a difference between the sensor output voltages at the points 3 and 4 is obtained as an optical sensor output difference corresponding to a voltage difference of D.R.=0.64 V. Thus, it can be understood that the results shown in respective FIGS. 4 and 5 are identical with each other. However, the optical sensor circuit 62 of the present embodiment can obtain a similar detection performance by using a photodiode and capacitor whose size are smaller than the photodiode and the capacitor of the conventional optical sensor circuit 102. This can increase the aperture ratio in the display region. As described above, the optical sensor circuit 62 of the present example is higher than the conventional sensor circuit 102 in terms of light detection performance per device unit-size.

The present embodiment is different from a conventional technique that produces a difference in an optical sensor output for an intensity of light irradiation on a photodiode by directly changing a given electrode potential of the field-effect transistor, which serves as an optical sensor output device. The present embodiment is a technique capable of producing a difference in an optical sensor output indirectly by not directly changing any electrode potential of the field-effect transistor but changing the threshold voltage of the common-drain field-effect transistor (i.e., the field-effect transistor capable of outputting an amplified output from the source). Consequently, it is possible to simply the method for driving the optical sensor circuit and to reduce a shift in the threshold voltage of the filed-effect transistor.

According to the optical sensor circuit 62, thus, when the capacitor 62c is charged via the photodiode 62b being conductive in the forward direction, the voltage VnetA at the node netA is applied to the back gate 62ag2 of the TFT 62a. This causes a change in the threshold voltage of the TFT 62a. Thereafter, when the reverse bias voltage is applied to the photodiode 62b, the voltage at the node netA, i.e., the voltage at the back gate 62ag2, is changed depending on the intensity of the light irradiation on the photodiode 62b. When the voltage for causing the TFT 62a to be in the ON state is applied to the gate 62ag1 of the TFT 62a, the voltage corresponding to the voltage VnetA, i.e., the voltage corresponding to the intensity of the light irradiation, can be outputted from the source of the TFT 62a. Further, since the TFT 62a functions as a type of a source follower, it has a great current output ability and is thereby capable of performing power amplifying.

The voltage applied to the gate 62ag1 of the TFT 62a is the voltage applied via the readout control line Vrwn. For this reason, even if light irradiation on respective optical sensors 62 are different from each other, there is less likely a variation in size of shift phenomena of threshold voltages of respective TFTs 62a.

With the above, the display device can be realized in which it is possible that the TFTs, which serve as output amplifiers for efficiently increasing week outputs of photodiodes, are such that their shift phenomena of threshold voltages are uniform with each other.

The following describes detailed pattern positioning in a display region according to the present embodiment.

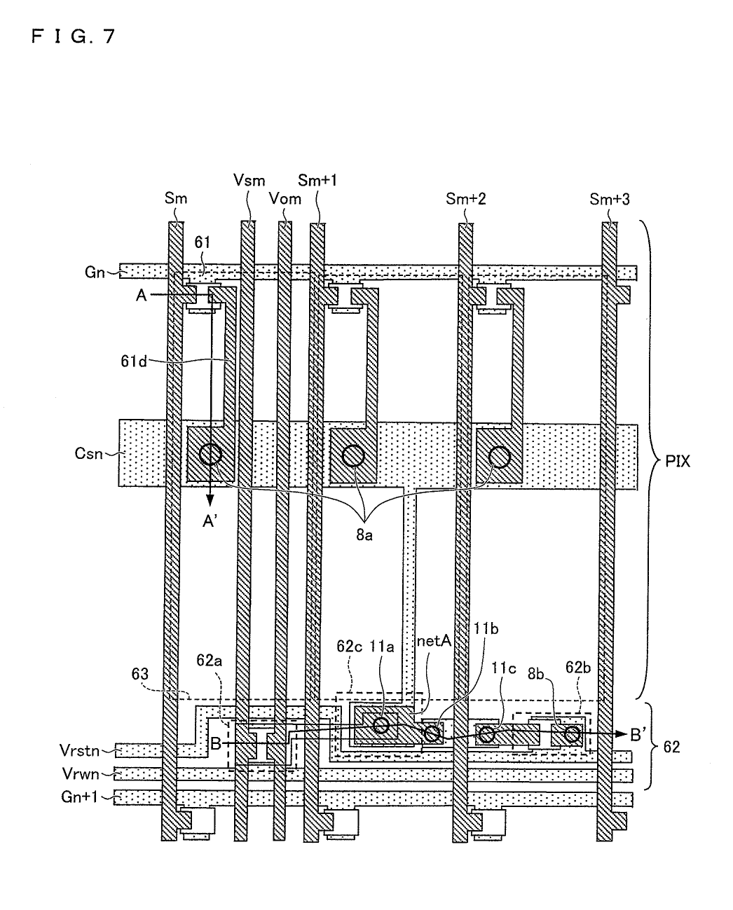

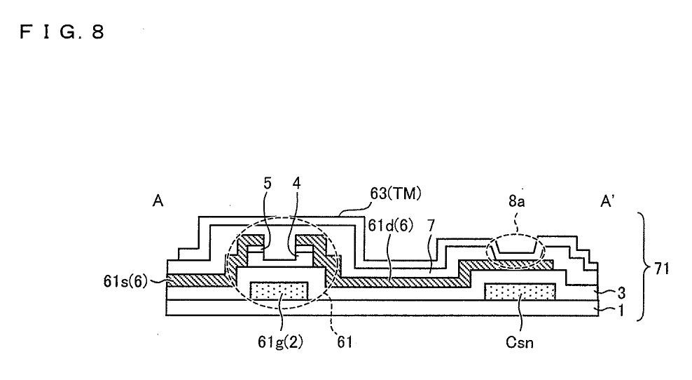

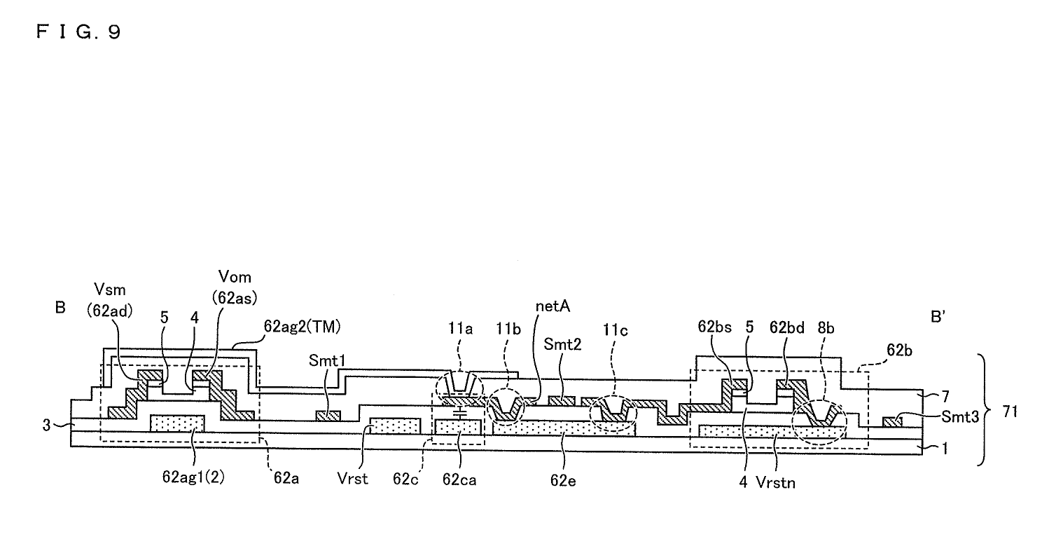

FIG. 7 is a plan view showing a part of a display region according to a first pattern positioning example which is a pattern positioning example of the present embodiment. FIG. 7 shows a pattern view corresponding to the circuit view shown in FIG. 1. FIG. 8 is a cross sectional view of a picture element PIX taken along the line A-A′ of FIG. 7. FIG. 9 is a cross sectional view of the sensor circuit 62 taken along the line B-B′ of FIG. 7.

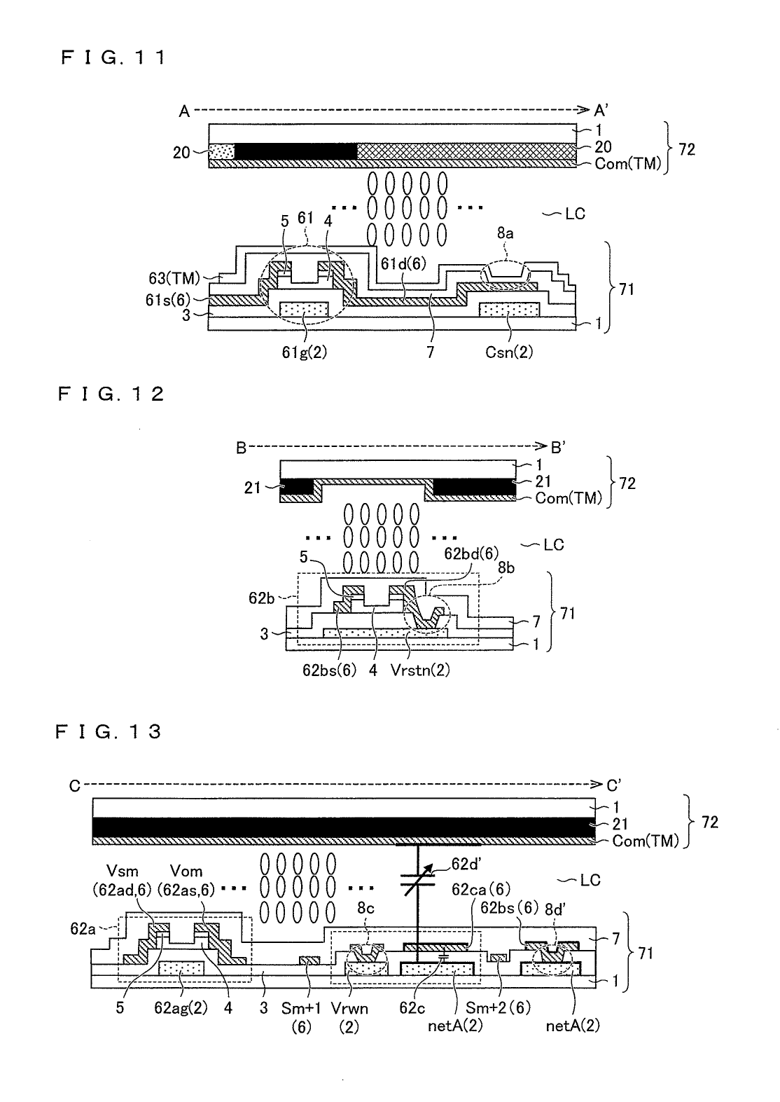

FIG. 7 shows a case where the sensor output line Vom and the power source line Vsm are provided independently of the source line S. Since the counter substrate and the liquid crystal layer have configurations similar to those shown in FIGS. 11 through 13 (which are later described), their illustrations and explanations are omitted here.

In the first pattern positioning example, as shown in FIG. 9, the TFT 62a which serves as the output amplifier is an inversely staggered TFT, and the back gate 62ag2 is provided in a top side of the TFT substrate 71. However, the present invention is not limited to this. The TFT 62a may be alternatively a forwardly staggered TFT, and the back gate 62ag2 may be alternatively provided in a bottom side of the TFT substrate 71.

As shown in FIGS. 8 and 9, the TFT substrate 71 includes the insulating substrate 1, a gate metal 2, a gate insulating film 3, an amorphous silicon semiconductor layer 4, an n⁺ amorphous silicon contact layer 5, a source metal 6, a passivation film 7, and a transparent electrode TM which are layered in this order. An alignment film may be provided above the transparent electrode TM. Further, a phototransistor 62b is formed by connecting a gate and a drain of a TFT to each other.

The gate metal 2 forms the gate electrode 61g of the TFT 61, the retention capacitor line Csn, the reset line Vrstn, the readout control line Vrwn, the gate electrode 62ag1 of the TFT 62a, an electrode 62ca of the capacitor 62c which electrode 62ca is provided in a side opposite to a side on which the node netA is provided, and an intermediate connect pad 62e. The source metal 6 forms the source lines S (Sm, Sm+1, . . . ), the source electrode 61s of the TFT 61, the drain electrode 61d of the TFT 61, a source electrode 62bs of the photodiode 62b, a drain electrode 62bd of the photodiode 62b, the sensor output line Vom that also serves as the source electrode 62 as of the TFT 62a, the power source line Vsm that also serves as the drain electrode 62ad of the TFT 62a, and the node netA. The transparent electrode TM forms the picture element electrode 63 and the back gate 62ag2 of the TFT 62a. The back gate 62ag2 thus formed is provided in a back-channel side of the TFT 62a.

The picture element electrode 63 and the drain electrode 61d of the TFT 61 are connected with each other via a contact hole 8a opened in the passivation film 7. The drain electrode 62bd of the photodiode 62b and the reset line Vrstn are connected with each other via a contact hole 8b opened in the gate insulating film 3. The back gate 62ag2 and the node netA are connected with each other via a contact hole 11a opened in the passivation film 7. The electrode 62ca of the capacitor 62c is connected with the retention capacitor line Csn. The node netA and an intermediate connect pad 62e are connected with each other via a contact hole 11b opened in the gate insulating film 3. The source electrode 62bs of the photodiode 62b and the intermediate connect pad 62e are connected with each other via a contact hole 11c opened in the gate insulating film 3.

In the first pattern positioning example, the TFT 62a is the inversely staggered TFT and the back gate 62ag2 is formed by the transparent electrode TM. Thus, the back gate 62ag2 can be provided simply by additionally patterning it on an upper part of the TFT 62a. This makes it easier to manufacture the TFT 62a. An existing film provided for use in the picture element electrode 63 can be also used as the transparent electrode TM. This can simplify a film configuration and the manufacturing process.

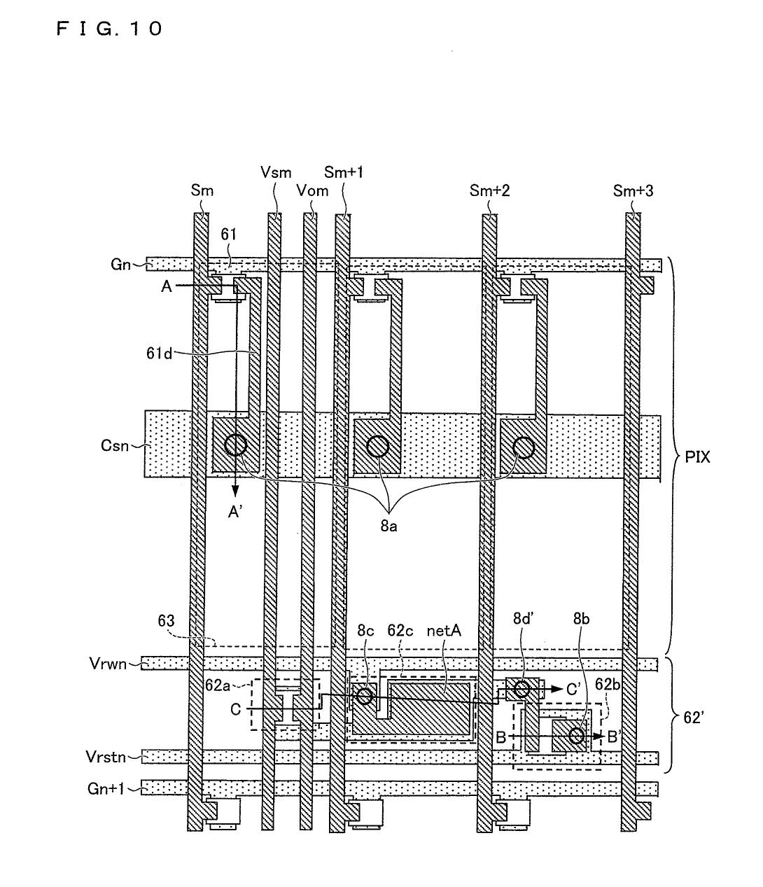

Each of FIGS. 10 through 13 shows a second pattern positioning example which is an pattern positioning example in a conventional optical sensor circuit. FIG. 10 is a plan view, FIG. 11 is a cross sectional view taken along the line A-A′ of FIG. 10, FIG. 12 is a cross sectional view taken along the line B-B′ of FIG. 10, and FIG. 13 is a cross sectional view taken along the line C-C′ of FIG. 10. In each of FIGS. 10 through 13, members similar to the members shown in FIGS. 7 through 9 are given like reference signs. In place of the optical sensor circuit 62, a sensor circuit 62′ is provided.

A counter substrate 72 includes an insulating substrate 1, a color filter 20, a black matrix 21, and a common electrode Com which are layered in this order. An alignment film may be provided above the common electrode Com. The common electrode Com is formed by a transparent electrode TM. A liquid crystal layer LC is provided between a TFT substrate 71 and the counter substrate 72.

In the second pattern positioning example, a node netA is formed by a gate metal 2. The node netA is provided so as to be bottommost among conductive layers provided on the insulating substrate 1 of the TFT substrate 71. Unlike in the first pattern positioning example, a TFT 62a has no back gate. The source metal 6 forms an electrode 62ca of a capacitor 62c which electrode 62ca is provided in an opposing side to the node netA. The electrode 62ca is connected with a readout control line Vrwn via a contact hole 8c opened in a gate insulating film 3. A source electrode 62bs of a photodiode 62b is connected via a contact hole 8d′ opened in a part between the photodiode 62b and the node netA.

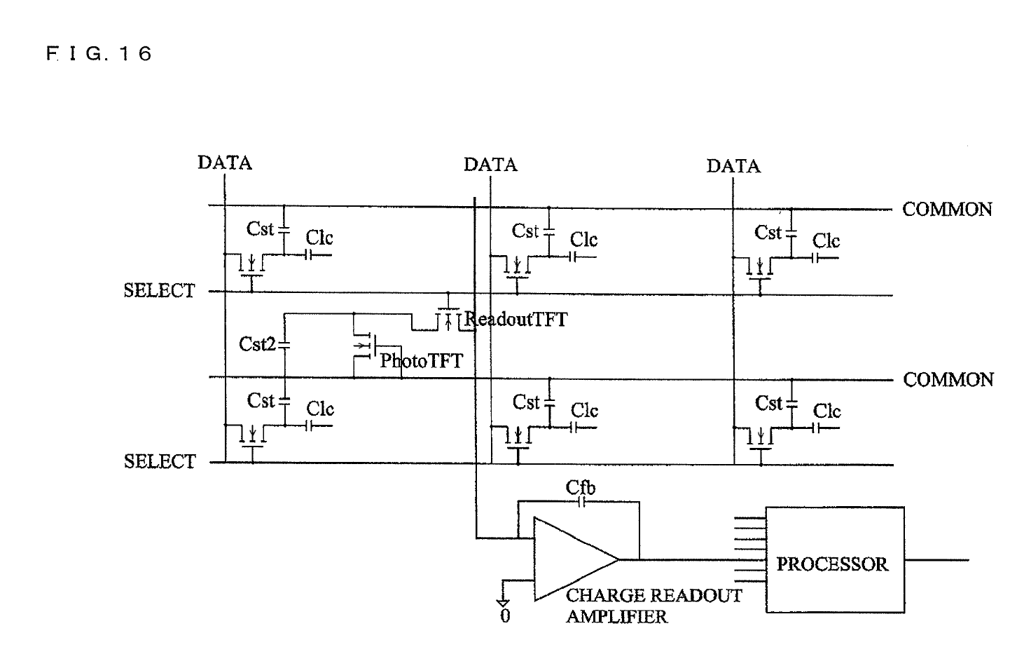

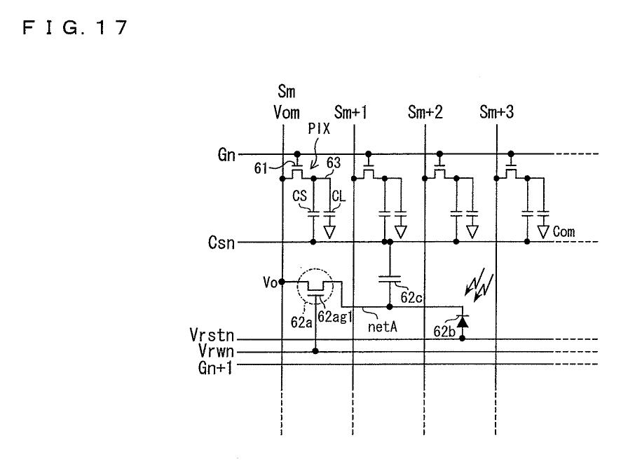

The optical sensor circuit 62 of the present embodiment can produce the following effect, as compared to the configuration shown in FIG. 17 which is equivalent to the configuration of the conventional art shown in FIG. 16.

In the configuration shown in FIG. 17, a node netA is connected with a drain of a TFT 62a which serves as an output amplifier. In view of this, it is necessary that load charging be carried out via a source of the TFT 62a by an electrostatic energy stored in a capacitor 62c. A gate 62ag1 of the TFT 62a is connected with a readout control line Vrwn. Accordingly, the capacitor 62c has an increased capacitance value, and a photodiode 62b used in the configuration has a great resistance to a reverse voltage or is great in size, so as to have a current capacity sufficient to quickly charge the capacitor 62c. Thus, an aperture ratio in the display region is decreased. In contrast, according to the sensor circuit 62 of the present embodiment, the capacitor 62c has to charge only a small capacitor of the back gate 62ag2 of the TFT 62a. Therefore, an output of the photodiode 62b can be a week electric power. The TFT 62a which serves as the output amplifier can use the voltage applied via the power source line Vsm so as to perform load charging by a great driving ability.

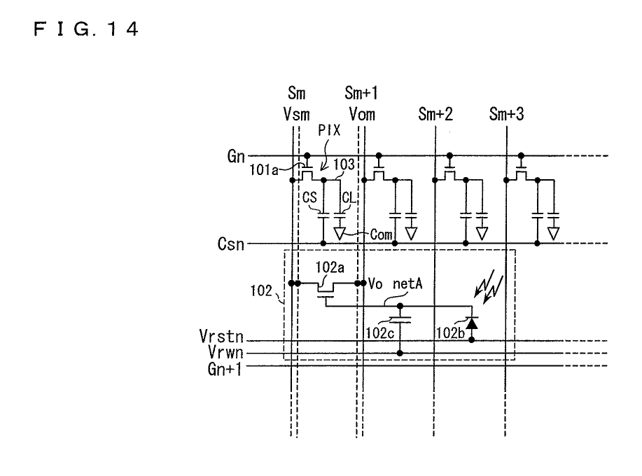

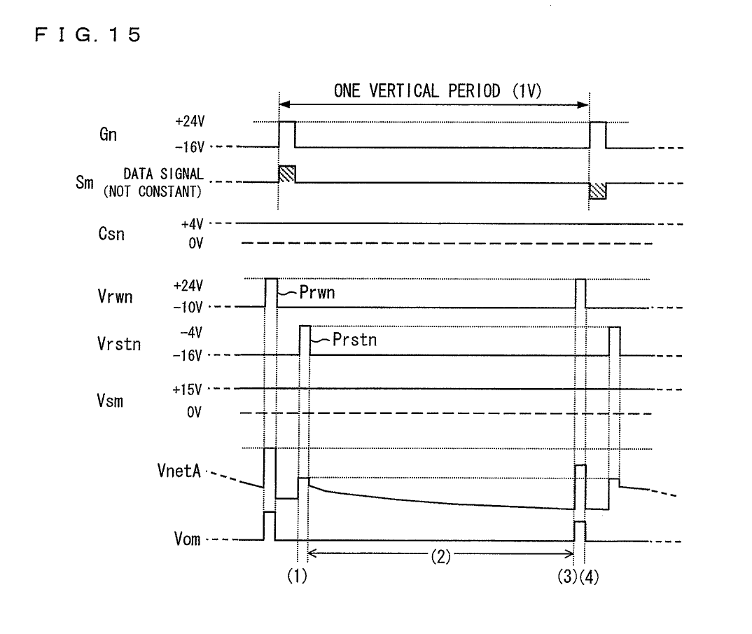

As such, the sensor circuit 62 of the present embodiment can dissolve a trade-off between a good sensor detection sensitivity and a sufficient aperture ratio which trade-off is caused in the configurations shown in FIGS. 14 and 17.

The present Embodiment has been described as above. Examples of the photodiode used in the present invention encompass various transistors, such as diode-connected field-effect transistors mentioned in the first pattern positioning example and bipolar transistors (including phototransistors). Examples of the photodiode also encompass photodiodes having normal diode laminate structures, such as pin-photodiodes. That is, the photodiode used in the present invention may be any device whose current-voltage properties have diode properties and whose internal conductivity changes due to irradiation with light.

In order to attain the object, an optical sensor circuit of the present invention at least includes: a photodiode; and a common-drain field-effect transistor whose threshold voltage changes depending on an intensity of light irradiation to the photodiode.

The invention is a technique capable of producing a difference in an optical sensor output indirectly by not directly changing an electrode potential of the filed-effect transistor but changing the threshold voltage of common-drain field-effect transistor (i.e., the field-effect transistor capable of outputting an amplified output from a source), unlike the conventional art that produces a difference in an optical sensor output for the intensity of the light irradiation on the photodiode by directly changing a given electrode potential of the field-effect transistor, which serves as an optical sensor output device. The invention thus brings about an effect that the method for driving the optical sensor circuit is simplified and a shift in threshold voltage of the filed-effect transistor is reduced.

In order to attain the object, the optical sensor circuit of the present invention further includes: a first circuit including the photodiode, a first capacitor, and an output amplifier which is a common-drain field-effect transistor, the common-drain field-effect transistor having a back gate, a cathode of the photodiode, a first end of the first capacitor, and the back gate of the common-drain field-effect transistor being connected with each other via a first node, an anode of the photodiode being connected with a first line via which a voltage is applied to the anode of the photodiode, a second end of the first capacitor being connected with a second line via which a voltage is applied to the second end of the first capacitor, a gate of the common-drain field-effect transistor being connected with a third line via which a voltage is applied to the gate of the common-drain field-effect transistor, a drain of the common-drain field-effect transistor being connected with a fourth line via which a voltage is applied to the drain of the common-drain field-effect transistor, and a source of the common-drain field-effect transistor being an output of the output amplifier.

According to the invention, since the field-effect transistor is the common-drain transistor, the amplifier output is outputted from the source of the filed-effect transistor. In a case where the first transistor is charged via the photodiode being conductive in the forward direction, the voltage at the first node is applied to the back gate of the field-effect transistor so as to cause a change in the threshold voltage of the field-effect transistor which is the output amplifier. Thereafter, the voltage is applied to the anode of the photodiode via the first line so as to apply the reverse bias to the photodiode. At that time, the voltage at the first node, i.e., the voltage at the back gate, is changed depending on the intensity of the light irradiation on the photodiode. When the voltage for causing the field-effect transistor to be in the ON state is applied to the gate of the field-effect transistor, the voltage (i.e., the voltage corresponding to the intensity of the light irradiation) corresponding to the voltage at the first node, i.e., the voltage at the back gate, can be outputted from the source of the field-effect transistor. Further, since the filed-effect transistor functions as a type of a source follower, it has a great current output ability and is thereby capable of performing power amplifying.

The voltage applied to the gate of the field-effect transistor is the voltage applied via the third line. For this reason, even if light irradiation histories of respective first circuits are different from each other, there are less likely variations in sizes of shift phenomena of threshold voltages of field-effect transistors.

With the above, it is possible to bring about an effect that realizes the optical sensor circuit in which the TFTs, which serve as output amplifiers for efficiently increasing week outputs of photodiodes, are such that their shift phenomena of threshold voltages are uniform with each other.

In order to attain the object, the optical sensor circuit of the present invention is configured so that the common-drain field-effect transistor is an inversely staggered TFT.

According to the invention, since the field-effect transistor is the inversely staggered TFT, the back gate can be formed by additionally patterning it on an upper portion of the field-effect transistor. This can bring about an effect that makes it easier to manufacture the filed-effect transistor which serves as the output amplifier.

In order to attain the object, the optical sensor circuit of the present invention is configured so that: a first predetermined direct voltage is applied to the second line, and a second predetermined direct voltage is applied to the fourth line, a first pulse for causing the photodiode to be conductive in a forward direction is applied to the first line, a reverse bias voltage is applied to the photodiode when a period during which the first pulse is applied to the photodiode is ended, a second pulse is applied to the third line when a predetermined period is passed after the end of the period, so as to change an OFF state of the common-drain field-effect transistor to an ON state, and an output voltage from the output of the output amplifier is obtained in a period during which the second pulse is applied.

According to the invention, when the period during which the first pulse is applied to the photodiode is ended, the photodiode is in such a state that the reverse bias voltage is applied to the photodiode. As such, in the predetermined period, a leak current having a level being dependent on the intensity of the light irradiation on the photodiode occurs in the photodiode so that the voltage at the first node corresponds to the intensity of the light irradiation. Thereafter, after the predetermined period, the second pulse is applied via the third line so as to change the OFF state of the field-effect transistor to the ON stat. At that time, since the back gate voltage corresponds to the intensity of the light irradiation, the output voltage of the output amplifier corresponds to the intensity of the light irradiation.

With this, it is possible to bring about an effect that obtains, from the output amplifier, a suitable output voltage corresponding to the intensity of the light irradiation.

In order to attain the object, the display device of the present invention includes the optical sensor circuit.

According to the invention, the optical sensor circuit is provided in the display device. As such, even if the first capacitor or the photodiode is smaller in device size than a capacitor or a photodiode of a conventional optical sensor circuit, it is possible to obtain a similar optical sensor output difference. This can bring about an effect that prevents a decrease in an aperture ratio.

In order to attain the object, the display device of the present invention includes the optical sensor circuit, the back gate being formed by a transparent electrode.

According to the invention, the transparent electrode can be an existing film provided for use in a picture electrode, for example. This can bring about an effect that simplifies a film structure and a manufacturing process.

In order to attain the object, the display device of the present invention includes the optical sensor circuit, the fourth line being a data signal line.

According to the invention, the fourth line is the data signal line. This can bring about an effect that reduces the number of lines.

In order to attain the object, the display device of the present invention includes the optical sensor circuit, the fourth line being a fifth line provided independently of a data signal line.

According to the invention, the fourth line is the fifth line provided independently of the data signal lines. This can bring about an effect that can carry out voltage application to the fourth line for purpose of detection of the intensity of the light irradiation, irrespectively of whether the timing of voltage application is in the writing period during which data signals are written or not.

In order to attain the object, the display device of the present invention includes the optical sensor circuit, a line to which the source of the common-drain field-effect transistor is connected being a data signal line.

According to the invention, the line to which the source of the common-drain field-effect transistor is connected is the data signal line. This brings about an effect that can reduce the number of lines.

In order to attain the object, the display device of the present invention includes the optical sensor circuit, the line to which the source of the common-drain field-effect transistor is connected being a sixth line provided independently of a data signal line.

According to the invention, the line to which the source of the common-drain filed-effect transistor is connected is the sixth line provided independently of the data signal line. This can bring about an effect that can obtain an output from the output amplifier for purpose of detection of the intensity of the light irradiation, irrespectively of whether the timing of the output obtaining is in the writing period during which data signals are written or not.

In order to attain the object, the display device of the present invention is a liquid crystal display device, including the optical sensor circuit, the second line being a retention capacitor line.

According to the invention, the second line is the retention capacitor line. This brings about an effect that can reduces the number of lines.

In order to attain the object, a method of the present invention for driving an optical sensor circuit including a first circuit, the first circuit including a photodiode, a first capacitor, and an output amplifier which are provided in a display region, the output amplifier being a field-effect transistor, the field-effect transistor having a back gate, a cathode of the photodiode, a first end of the first capacitor, and the back gate being connected with each other via a first node, an anode of the photodiode being connected with a first line via which a voltage is applied to the anode of the photodiode, a second end of the first capacitor being connected with a second line via which a voltage is applied to the second end of the first capacitor, a gate of the field-effect transistor being connected with a third line via which a voltage is applied to the gate of the field-effect transistor, a drain of the field-effect transistor being connected with a fourth line via which a voltage is applied to the drain of the filed-effect transistor, and a source of the filed-effect transistor being an output of the output amplifier, the method including the steps of: applying a first predetermined direct voltage to the second line and a second predetermined direct voltage to the fourth line; applying, to the first line, a first pulse for causing the photodiode to be conductive in a forward direction; applying a reverse bias voltage to the photodiode when a period during which the first pulse is applied is ended; applying a second pulse to the third line when a predetermined time is passed after the end of the period, so as to change an OFF state of the field-effect transistor to an ON state; and obtaining an output voltage from the output of the output amplifier in a period during which the second pulse is applied to the third line.

According to the invention, when the period during which the first pulse is applied to the photodiode is ended, the reverse bias voltage is applied to the photodiode. As such, within the predetermined period, a leak current having a level being dependent on the intensity of the light irradiation on the photodiode occurs in the photodiode so that the voltage at the first node corresponds to the intensity of the light irradiation. Thereafter, after the predetermined period has been passed, the second pulse is applied via the third line so as to change the OFF state of the field-effect transistor to the ON state. At that time, since the back gate voltage corresponds to the intensity of the light irradiation, the output voltage of the output amplifier corresponds to the intensity of the light irradiation.

With this, it is possible to obtain, from the output amplifier, a suitable output voltage corresponding to the intensity of the light irradiation.

With the above, it is possible to bring about an effect that can realize the method for driving the optical sensor circuit, according to which method it is possible that the TFTs, which serves as output amplifier for efficiently increasing week outputs of photodiodes, are so that their shift phenomena of threshold voltages are unique with each other.

The present invention is not limited to the embodiments above, but may be a combination of the embodiments or altered by a skilled person within the scope of the claims. An embodiment based on a proper combination of technical means altered as appropriate within the scope of the claims is encompassed in the technical scope of the present invention.

### INDUSTRIAL APPLICABILITY

The present invention is suitably usable to various display devices such as a liquid crystal display device.

### REFERENCE SIGNS LIST

50: liquid crystal display device (display device)
51: display panel
62a: TFT (field-effect transistor, output amplifier)
62ag1: gate
62ag2: back gate
62b: photodiode
62c.: capacitor (first capacitor)
net A: node (first node)
Prst: reset pulse (first pulse)
Prw: readout pulse (second pulse)
Vrst, Vrstn: reset line (first line)
Csn: retention capacitor line (second line)
Vrw, Vrwn: readout control line (third line)
S, Sm+1: source line (fourth line, data signal line)
Vs, Vsm: power source line (fourth line, data signal line, fifth line)
S, Sm: source line (line to which source of field-effect transistor is connected, data signal line)
Vo, Vom: sensor output line (line to which source of field-effect transistor is connected, data signal line, sixth line)

1. An optical sensor circuit at least comprising:
a photodiode; and
a common-drain field-effect transistor whose threshold voltage changes depending on an intensity of light irradiation to the photodiode.

2. The optical sensor circuit as set forth in claim 1, further comprising:
a first circuit including the photodiode, a first capacitor, a second capacitor, and an output amplifier which is the common-drain field-effect transistor,
the common-drain field-effect transistor having a back gate,
a cathode of the photodiode, a first end of the first capacitor, and the back gate of the common-drain field-effect transistor being connected with each other via a first node,
an anode of the photodiode being connected with a first line via which a voltage is applied to the anode of the photodiode,
a second end of the first capacitor being connected with a second line via which a voltage is applied to the second end of the first capacitor,
a gate of the common-drain field-effect transistor being connected with a third line via which a voltage is applied to the gate of the common-drain field-effect transistor,
a drain of the common-drain field-effect transistor being connected with a fourth line via which a voltage is applied to the drain of the common-drain field-effect transistor, and
a source of the common-drain field-effect transistor being an output of the output amplifier.

3. The optical sensor circuit as set forth in claim 2, wherein the common-drain field-effect transistor is an inversely staggered TFT.

4. The optical sensor circuit as set forth in claim 2, wherein
a first predetermined direct voltage is applied to the second line, and a second predetermined direct voltage is applied to the fourth line,
a first pulse for causing the photodiode to be conductive in a forward direction is applied to the first line,
a reverse bias voltage is applied to the photodiode when a period during which the first pulse is applied to the photodiode is ended,
a second pulse is applied to the third line when a predetermined period is passed after the end of the period, so as to change an OFF state of the common-drain field-effect transistor to an ON state, and
an output voltage from the output of the output amplifier is obtained in a period during which the second pulse is applied.

5. A display device comprising:
an sensor circuit as set forth in claim 1.

6. A display device comprising:
an optical sensor circuit as set forth in claim 3,
the back gate being formed by a transparent electrode.

7. A display device comprising:
an optical sensor circuit as set forth in claim 2,
the fourth line being a data signal line.

8. A display device comprising:
an optical sensor circuit as set forth in claim 2,
the fourth line being a fifth line provided independently of a data signal line.

9. A display device comprising:
an optical sensor circuit as set forth in claim 2,
a line to which the source of the common-drain field-effect transistor is connected being a data signal line.

10. A display device comprising:
an optical sensor circuit as set forth in claim 2,
a line to which the source of the common-drain field-effect transistor is connected being a sixth line provided independently of a data signal line.

11. A liquid crystal display device, comprising:
an optical sensor circuit as set forth in claim 2,
the second line being a retention capacitor line.

12. A method for driving an optical sensor circuit including a first circuit,
the first circuit including a photodiode, a first capacitor, a second capacitor, and an output amplifier which are provided in a display region, the output amplifier being a field-effect transistor,
the field-effect transistor having a back gate,
a cathode of the photodiode, a first end of the first capacitor, and the back gate being connected with each other via a first node,
an anode of the photodiode being connected with a first line via which a voltage is applied to the anode of the photodiode,
a second end of the first capacitor being connected with a second line via which a voltage is applied to the second end of the first capacitor,
a gate of the field-effect transistor being connected with a third line via which a voltage is applied to the gate of the field-effect transistor,
a drain of the field-effect transistor being connected with a fourth line via which a voltage is applied to the drain of the filed-effect transistor, and
a source of the filed-effect transistor being an output of the output amplifier,
the method comprising the steps of:
applying a first predetermined direct voltage to the second line and a second predetermined direct voltage to the fourth line;
applying, to the first line, a first pulse for causing the photodiode to be conductive in a forward direction;
applying a reverse bias voltage to the photodiode when a period during which the first pulse is applied is ended;
applying a second pulse to the third line when a predetermined time is passed after the end of the period, so as to change an OFF state of the field-effect transistor to an ON state; and
obtaining an output voltage from the output of the output amplifier in a period during which the second pulse is applied to the third line.
